(19) United States
(12) Patent Application Publication
(10) Pub. No.: US 2023/0235445 A1
(43) Pub. Date: Jul. 27, 2023

(54) COATING DEVICE FOR DEPOSITING A COATING MATERIAL ON A SUBSTRATE

(71) Applicant: ThyssenKrupp Steel Europe AG, Duisburg (DE)

(72) Inventors: Janine-Christina SCHAUER-PASS, Dorsten (DE); Christian SCHWERDT, Duisburg (DE); Michael STRACK, Recklinghausen (DE); Maurizio GIORGIO, Dresden (DE); Slavcho TOPALSKI, Dresden (DE); Axel ZWICK, Dresden (DE); Teja ROCH, Dresden (DE)

(21) Appl. No.: 18/014,659

(22) PCT Filed: Jun. 22, 2021
(86) PCT No.: PCT/EP2021/066897

§ 371 Date: Jan. 5, 2023

(30) Foreign Application Priority Data
Jul. 8, 2020 (DE) 10 2020 118 015.2

(51) Int. Cl. C23C 14/24; C23C 14/32

(52) U.S. Cl. CPC C23C 14/246; C23C 14/243; C23C 14/325; C23C 4/131

(57) ABSTRACT

A coating device includes a vacuum chamber, a crucible, at least one spray head for preparing the coating material, and an injector tube, wherein the injector tube is designed to conduct the prepared coating material to the crucible and is connected to the crucible, wherein the at least one spray head can be moved between an operating position, in which the spray head supplies the injector tube with the prepared coating material, and a removal position, and wherein at least one removal chamberis provided which is designed to be accessible from outside the vacuum chamber and which can be sealed off from the vacuum chamber and in which the at least one spray headin its removal position is separated from the vacuum chamber in a gas-tight manner.

### BACKGROUND

The subject disclosure relates to a coating device for depositing a coating material on a substrate, wherein the coating device comprises a vacuum chamber, a crucible, which is arranged within the vacuum chamber, at least one spray head for preparing the coating material and an injector tube arranged within the vacuum chamber, wherein the injector tube is designed to conduct the coating material, which is prepared in the at least one spray head, to the crucible and is connected to the crucible.

A coating device of the aforementioned type is known, for example, from WO 2016/042079 A1. In this known coating device, two wires are continuously supplied as a coating material, wherein the coating material reaches a spray head, in which the two material wires form a cathode and an anode and are connected to an electrical DC voltage source, so that an electric arc is formed between the two material wires, as a result of which the coating material provided in the form of the two material wires is evaporated and/or liquefied. Furthermore, the spray head is provided with a gas flow which conducts the evaporated or liquefied coating material to a crucible via an injector tube. The coating material conducted to the crucible then evaporates completely within the heated crucible and is guided from the crucible onto the substrate to be coated, wherein the substrate can be, for example, a steel strip. To ensure the absence of oxygen, the coating process takes place in a vacuum chamber at pressures significantly below the atmospheric pressure.

It is possible for an injection head to fail during the operation of such a known coating device and need to be replaced, with regular maintenance of an injection head possibly being necessary as well. To remove an injection head from the vacuum chamber of the coating device, the entire coating device has to be stopped, cooled, and completely ventilated, which takes up a lot of time, is very complicated and results in a considerable loss of production.

### SUMMARY

An object of the present disclosure is to find a solution that provides an improved coating device in a structurally simple manner, by means of which the effort associated with the maintenance and replacement of an injection head can be reduced and operational interruptions can be reduced to a minimum.

According to one aspect, this object is achieved by a coating device with the features according to claim 1.

According to this or another aspect, the coating device for depositing a coating material on a substrate has a vacuum chamber, one or more crucibles formed for the warming and optionally the post-evaporation process, which is arranged within the vacuum chamber, at least one spray head designed for preparing the coating material, and an injector tube arranged within the vacuum chamber. The injector tube is designed to conduct the coating material prepared in the at least one spray head to the crucible, wherein the at least one spray head has an outlet opening for the prepared coating material and is designed to be movable between an operating position, in which the at least one spray head is arranged to supply the injector tube with the coating material provided, and a removal position. In this case, at least one removal chamber designed to be accessible from outside the vacuum chamber is provided, which is configured to be sealed off from the vacuum chamber and in which at least the outlet opening of the at least one spray head in the removal position of the spray head is separated in a gas-tight manner from the vacuum chamber. In this case, the crucible is designed to keep the coating material warm and optionally to re-evaporate said material, wherein the actual heating of the coating material takes place in the at least one spray head. In its operating position, the at least one spray head is sealed off against the injector tube in a steam-tight manner.

Advantageous and expedient embodiments and developments of the subject disclosure can also be found in the dependent claims.

According to an aspect, the subject disclosure provides a coating device which is characterized by a simple design and which makes it possible to remove a spray head from a coating device in a comparatively short time and with simple means and to replace said spray head, for example, with a new spray head. Due to the fact that the at least one spray head in its removal position within the removal chamber is separated in a gas-tight manner from the vacuum chamber, said spray head can be removed for repair and maintenance purposes from the removal chamber, which is accessible from outside the vacuum chamber, during the ongoing operation of the coating device, without interrupting the vacuum of the vacuum chamber.

To realize a compact design, the subject disclosure provides that the at least one spray head has at least one coating material feed and at least one gas feed, wherein, in the operating position of the at least one spray head, the at least one coating material feed and the at least one gas feed are guided through a vacuum feedthrough from outside the vacuum chamber into the vacuum chamber. By means of the vacuum feedthrough, the different feeds are consequently guided from outside the vacuum chamber through the vacuum feedthrough into the vacuum chamber to the spray head.

According to one embodiment, the movable design of the at least one spray head is realized in that the at least one spray head is attached to a flange which is connected to a wall portion of the vacuum chamber by means of a bellows-like connecting element.

In one particular embodiment, particularly small installation space is taken up when the bellows-like connecting element forms the at least one removal chamber. In the extended or unfolded state of the bellows-like connecting element, the connecting element itself offers sufficient space to be able to accommodate the spray head, which is to be accessed for maintenance or replacement reasons.

For a removal of the spray head during the operation of the coating device, it is provided in one embodiment that, in the removal position, the at least one spray head is arranged completely within the bellows-like connecting element. In this case, the bellows-like connecting element is formed elastically and in the manner of a tube that folds together in an accordion-like manner.

Another possibility for removing the spray head during the operation of the coating device is provided in one further embodiment in that a chamber wall element forms the at least one removal chamber and by means of a sealing element seals off against the at least one spray head, which can be moved from the operating position into the removal position and back. The sealing element can, for example, be an O ring.

According to one embodiment, the at least one spray head is attached to a flange at its longitudinal end facing away from the outlet opening, wherein the vacuum feedthrough is formed on the flange.

In a further embodiment, the vacuum feedthrough can be formed on the flange. In this case, a conceivable variant provides that the flange can be connected to a wall portion of the vacuum chamber via the bellows-like connecting element.

As an alternative embodiment, it is also conceivable for the vacuum feedthrough to be formed and arranged within the at least one spray head.

Furthermore, it is conceivable according to a further embodiment that the removal chamber is arranged horizontally and formed inside or outside the vacuum chamber.

In a further embodiment, it is structurally favorable if the at least one spray head is attached to the flange, wherein, in the removal position, the at least one spray head is arranged completely within the bellows-like connecting element. Consequently, the spray head can be moved between its operating position and its removal position via the flange, which is therefore movably attached to the vacuum chamber via the bellows-like connecting element.

In order to maintain the vacuum, which prevails in the vacuum chamber during the operation of the coating device, when maintenance is performed or when a spray head is replaced, the invention provides in a further embodiment that a shutoff device is movably arranged within the vacuum chamber between a release position and a blocking position, wherein, in the blocking position, the shutoff device separates the at least one spray head arranged in its removal position in a gas-tight manner from the vacuum chamber.

In a further embodiment, the subject disclosure provides that the at least one removal chamber has a ventilation valve. As soon as the shutoff device is arranged in the blocking position and thus the spray head is separated from the vacuum chamber in a gas-tight manner, the removal chamber, in which the spray head to be maintained or replaced is arranged, can be flooded, for example with an inert gas, so that the cooled spray head can subsequently be removed.

The injector tube, through which the vaporized or melted coating material is conducted from the spray head to the crucible, is heated during the operation of the coating device to a predetermined temperature in order to prevent a condensation of the coating material in the injector tube. The predetermined temperature can, for example, be a temperature above the condensation temperature of the coating material supplied. For this reason, the subject disclosure provides in a further embodiment that the injector tube is produced from a high-temperature-resistant material, such as, for example, graphite, wherein, for material compatibility reasons, it may be necessary to coat the surfaces of the graphite that come into contact with gas or steam with ceramic layers or alternatively to make the injector tube completely from ceramic. Accordingly, the subject disclosure provides that the high-temperature-resistant material can be graphite or ceramic.

A particularly compact design of the coating device is provided in a further embodiment in that the at least one spray head, when in its operating position, projects at least in portions into the injector tube and the at least one spray head is designed to be coaxially movable in the injector tube and guided in a gas-tight manner during a movement from the operating position in the direction of the removal position.

In order to be able to keep the hot steam and the liquid in the crucible even when the spray head is to be removed or replaced for repair or maintenance purposes, it is provided in a further embodiment that the injector tube has a shutoff valve, which is designed to be movable between a release position and a blocking position, wherein the shutoff valve blocks a flow through the injector tube in the blocking position. This avoids, in particular, a contamination of the vacuum chamber with evaporation material. It is advantageous in this case if the shutoff valve is produced from a high-temperature-resistant material.

According to a further advantageous embodiment, the at least one spray head can, in the blocking position of the shutoff valve, be arranged at least in portions within the injector tube.

It goes without saying that the features mentioned above and those to be explained below can be used not only in the specified combination, but also in other combinations or in isolation, without departing from the scope of the subject disclosure.

### BRIEF DESCRIPTION OF THE DRAWINGS

Other details, features, and advantages of the subject matter of the present disclosure can be found in the following description in conjunction with the drawings, in which an exemplary and one preferred embodiment is shown.

In the drawing: FIG. 1 is a schematic illustration of a coating device with a spray head arranged in an operating position,

FIG. 2 is a schematic illustration of the coating device with the spray head arranged in an intermediate position,

FIG. 3 is a schematic illustration of the coating device with the spray head arranged in a removal position, and

FIG. 4 is a schematic illustration of a further coating device with a spray head arranged in an operating position.

### DETAILED DESCRIPTION

FIGS. 1 to 3 illustrate schematically a coating device 1 according to one aspect for depositing a coating material on a substrate, wherein the substrate can be a strip-shaped material made of steel. In this case, a wire-shaped material is provided to the coating device 1 via the coating material feeds 2 and 3, for example by means of drive rollers (not shown in the figures) in such a way that an arc can form between the two fed strands of the wire-shaped material when, by means of an electric DC voltage source, a material strand provided by the coating material feed 2 is formed as the cathode and a material strand provided by the coating material feed 3 is formed as the anode, as a result of which the end-face ends are evaporated and/or at least melted. Furthermore, a gas flow, by means of which the evaporated and/or melted coating material is introduced through an injector tube 5 into a crucible 6, which can be heated, for example, by an inductive heater and which can be thermally insulated in order to avoid heat losses, is fed, using a gas feed 4. The substrate to be coated is moved at a small distance from the opening of the crucible 6 at a suitable feed rate so that the evaporated coating material comes in contact with the surface of the substrate to be coated.

The unit, with which the coating material is prepared and forwarded to the injector tube 5, is designed as an injection head 7 which comprises the gas supply 4 and the coating material feeds 2 and 3. Furthermore, the spray head 7 designed to prepare the coating material can comprise a heater, a cooler and a nozzle conducting the prepared coating material into the injector tube 5, a cathode and an anode or an electrical DC voltage source. The spray head 7 should comprise the elements that are required to form an arc and a gas flow, wherein the elements for feeding wire-shaped or band-shaped coating material can also be part of the injection head 7. At least the part of the spray head 7 facing the injector tube 5, which has an outlet opening 17 from which the coating material prepared in the spray head 7 exits, is arranged within a vacuum chamber 8, wherein the crucible 6 and the injector tube 5, which is designed to conduct the coating material prepared in the spray head 7 to the crucible 6 and which is connected to the crucible 6, are arranged within the vacuum chamber 8. In order to prevent condensation of the coating material prepared in the injector tube 5, the injector tube 5 is heated to a predetermined temperature, wherein the predetermined temperature can, for example, be a temperature above the condensation temperature of the fed coating material. Therefore, the injector tube 5 can be produced from a high-temperature-resistant material, preferably graphite. For material compatibility reasons, it may be necessary to coat the surfaces of the graphite that are in contact with gas or melted materials with ceramic layers or to produce them completely in ceramic.

The coating material feeds 2 and 3 and the gas supply 5 are conducted by means of a vacuum feedthrough 18 from the atmosphere outside the vacuum chamber 8 into the vacuum or the interior of the vacuum chamber 8. Accordingly, the coating material feeds 2 and 3 and the gas supply 5 are conducted via the vacuum feedthrough 18 from outside the vacuum chamber 8 into the vacuum chamber 8. As is schematically indicated in FIGS. 1 to 3, the vacuum feedthrough 18 is formed on a flange 9. This flange 9 is arranged outside the vacuum chamber 8 and connected via a bellows-like connecting element 10 to a wall portion 11 of the vacuum chamber 8. In this case, the spray head 7 is attached to the flange 9, wherein the flange 9 is, in turn, connected to the vacuum chamber 8 via the bellows-like connecting element 10. The bellows-like connecting element 10 is attached to a through-opening of the vacuum chamber 8 so that the spray head 7 mounted on the flange 9 can be freely moved within the vacuum chamber 8. In FIG. 1, the spray head 7 is arranged in an operating position in which the spray head 7 is arranged to supply the injector tube 5 with the prepared coating material. In the operating position, the outlet opening 17 of the spray head 7, which is formed in the manner of a nozzle, i.e., the part of the spray head 7 facing the injector tube 5, projects into the injector tube 5, wherein the outlet opening 17 of the spray head 7 or the spray head 7 itself can be moved coaxially in the injector tube 5. In this case, the spray head 7 is guided in a gas-tight manner within the injector tube 5 and is arranged as far as possible in the injector tube 5 during the operation of the coating device 1. Consequently, the injector tube 5 connects the spray head 7 to the crucible 6 in a gas-tight manner when the spray head 7 is arranged in the operating position.

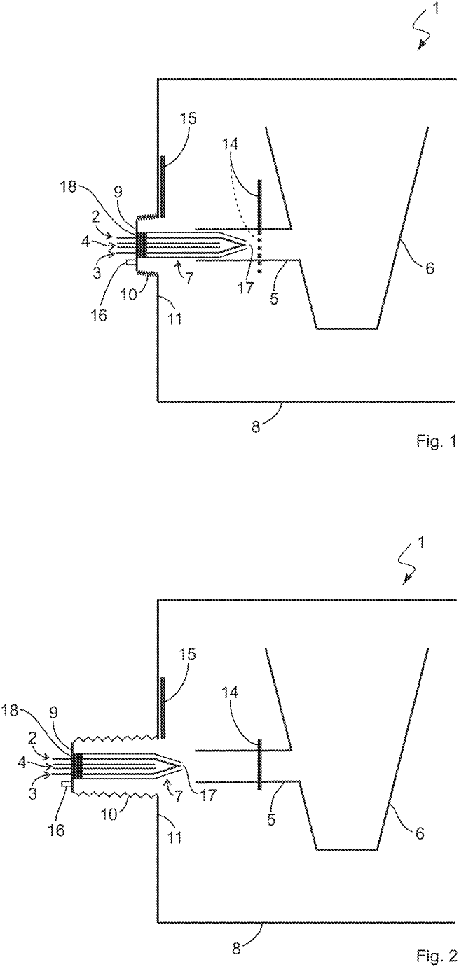

If the spray head 7 is to be removed for repair or maintenance reasons, the spray head 7 is switched off first by interrupting the gas supply via the gas feed 4 and by stopping the further supply of the spray head 7 with coating material via the coating material feeds 2 and 3, with the electrical power supply having to be switched off as well. A shutoff valve 14 is then moved from a release position shown in FIG. 1 into a blocking position shown in FIG. 2 in order to seal the injector tube 5 off from the vacuum chamber 8 before the spray head 7 is completely pulled out of the injector tube 5. Subsequently, the spray head 7 is pulled out of the injector tube 5 in order to be replaced, as shown in FIG. 2. Consequently, in order to remove the spray head 7, the spray head 7 remains in its operating position that seals it off in a steam-tight manner against the injector tube 5 until the shutoff valve 14 is in its blocking position. In FIG. 2, the spray head 7 is in an intermediate position in which the spray head 7 is arranged horizontally outside the injector tube 5. During this movement of the spray head 7, the bellows-like connecting element 10 is pulled apart, wherein the spray head 7 is arranged horizontally in portions within the connecting element 10 (see FIG. 2). The injector tube 5 is equipped with the shutoff valve 14, which can be closed from outside the vacuum chamber 8. This shutoff valve 14, which is also made of a high-temperature-resistant material, serves to keep the hot steam and the liquid in the crucible 6 in order to prevent a contamination of the vacuum chamber 8 with evaporation material. The shutoff valve 14 arranged in its closed position or blocking position (see for example FIG. 2) consequently blocks a flow through the injector tube 5 when the spray head 7 is arranged in its operating position or in its intermediate position or in a removal position, wherein the shutoff valve 14 has to be arranged in its blocking position even before the spray head 7 is moved completely out of the injector tube 5.

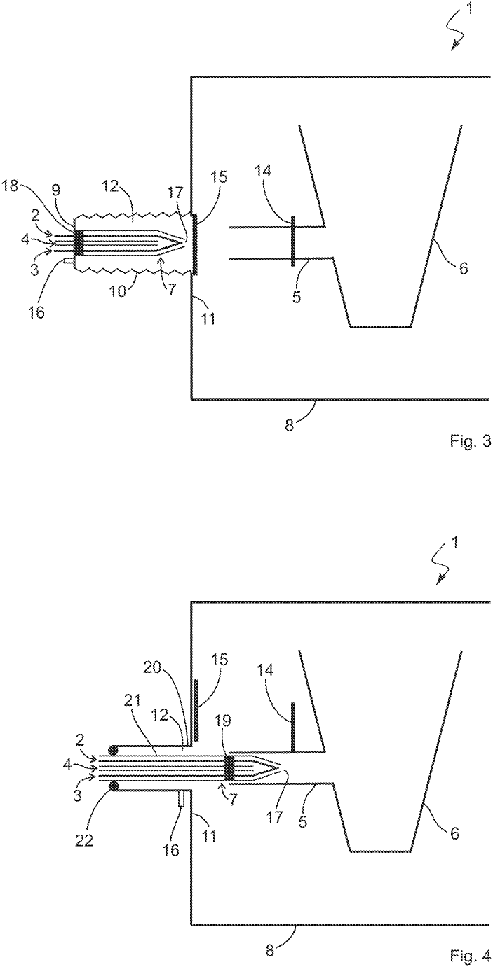

When the shutoff valve 14 is closed so that the spray head 7 is spatially separated from the hot steam and the liquid of the crucible 6, the flange 9 and the spray head 7 arranged thereon are moved into a direction pointing away from the crucible 6, as a result of which the spray head 7 is further retracted by the further extension of the bellows-like connecting element 10, as shown in FIG. 3. In FIG. 3, the spray head 7 is arranged in its removal position in which the spray head 7 is arranged completely within the bellows-like connecting element 10. In the removal position of the spray head 7, the bellows-like connecting element 10 forms a removal chamber 12 in which the outlet opening 17 of the spray head 7 is arranged. The removal chamber 12 is designed to be accessible from outside the vacuum chamber 8. In the embodiment shown in FIGS. 1 to 3, the removal chamber 12 is formed outside the vacuum chamber 8. It is also conceivable in an alternative embodiment that the removal chamber 12 is formed and arranged within the vacuum chamber 8. The removal chamber 12 is designed to be able to be sealed off from the vacuum chamber 8, wherein, in the removal chamber 12, the spray head 7 in its removal position is separated in a gas-tight manner from the vacuum chamber 8. For this purpose, when the spray head 7 is arranged in the removal position, a shutoff device 15, which is located for example on the wall portion 11 of the vacuum chamber 8, is closed, wherein the shutoff device 15 in this case is arranged in a blocking position (see FIG. 3), whereas the shutoff device 15 is arranged in a release position in FIGS. 1 and 2. The shutoff device 15 serves to maintain the vacuum in the vacuum chamber 8 and is produced in such a way that it can withstand high pressure differences. As soon as the shutoff device 15 is closed and the spray head 7 and the vacuum chamber 8 are separated from one another in a gas-tight manner, the bellows-like connecting element 10, in which the spray head 7 is located, can be flooded (preferably with an inert gas) by means of a ventilation valve 16. As can be seen from FIGS. 1 to 3, the ventilation valve 16 is arranged on the removal chamber 12. After the removal chamber 12 has been flooded and the spray head 7 cooled, the flange 9 can then be detached from the bellows-like connecting element 10 or the bellows-like connecting element 10 can be detached from the vacuum chamber 4 so that the cooled spray head 7 can subsequently be removed.

Preferably, the coating device 1 is equipped with at least two spray heads 7 so that one injection head 7 is always in operation while the other spray head 7 can be replaced. In order to be able to maintain the operation even in the case of a defective spray head 7, the vacuum chamber 8 is ideally equipped with three spray heads 7 so that, even in the case of maintenance, one injection head 7 is still in operation.

The maintained or repaired spray head 7 or a new spray head 7 is then installed in reverse order, wherein the connecting element 10 is evacuated after the spray head 7 is flange-mounted onto the bellows-like connecting element 10. Subsequently, the spray head 7 is heated and the shutoff device 15 and then the shutoff valve 14 are opened so that the spray head 7 enters the vacuum chamber 8 from the removal chamber 12 and can then be moved into the injector tube 5. Before the shutoff valve 14 is opened, the spray head 7 has to be arranged at least in portions within the injector tube 5, in which the spray head 7 is conducted in a coaxially movable and gas-tight manner.

FIG. 4 shows an alternative embodiment of the coating device 1 according to another aspect, wherein the same reference signs as for the embodiment shown in FIGS. 1 to 3 are used for the same components, and the above description with regard to the function and mode of operation also applies to the components of the alternative embodiment of FIG. 4 so that reference is made to the above description of these components. In FIG. 4, the spray head 7 is arranged in its operating position, in which the spray head 7 is arranged horizontally at least in portions within the injector tube 5 in a gas-tight manner. The embodiment of the coating device 1 shown in FIG. 4 has no vacuum feedthrough formed on a flange. Instead, in the embodiment shown in FIG. 4, a vacuum feedthrough 19 is arranged and formed in the spray head 7. In this case, the embodiment shown in FIG. 4 has no flange either on which the spray head 7 is attached. Instead, in the embodiment shown in FIG. 4, it is provided that a chamber wall element 20 forms the removal chamber 12. The chamber wall element 20 extends outside the vacuum chamber 8 at its wall portion 11 on the opening of the vacuum chamber 8. The chamber wall element 20 seals against the outer wall 21 of the spray head 7 by means of a sealing element 22. By means of this embodiment, the spray head 7 is designed to be able to be moved into its operating position or into its removal position, wherein the sealing element 22 seals the chamber wall element 20 and the outer wall 21 of the spray head 7 off from each other. The sealing element 22 can, for example, be designed as an O ring. In the removal position of the spray head 7 in the embodiment shown in FIG. 4, the outlet opening 17 is arranged within the removal chamber 12, wherein the removal chamber 12 can also be formed within the vacuum chamber 8 when the chamber wall element 20 extends within the vacuum chamber 8. To remove the spray head 7, the shutoff valve 14 is first closed and then the spray head 7 is moved into its removal position in which the outlet opening 17 is arranged horizontally such that it is within the removal chamber 12. The shutoff device 15 is then moved into its blocking position so that the removal chamber 12 is separated in a gas-tight manner from the vacuum chamber 8 in order to subsequently flood the removal chamber 12 via the ventilation valve 16, as has already been described for the embodiment of FIGS. 1 to 3.

It is apparent from the description of FIGS. 1 to 4 that further embodiments are conceivable. In the embodiment shown in FIGS. 1 to 3, for example, the vacuum feedthrough can be formed within the injection head 7 instead of on the flange 9, as shown in FIG. 4. It is also conceivable that in the embodiment shown in FIG. 4 a flange is attached to the longitudinal end of the spray head 7 facing away from the outlet opening 17, wherein a vacuum feedthrough is then arranged on the flange instead of a vacuum feedthrough within the injection head 7.

In summary, what is described above is the coating device 1 according to one aspect for depositing a coating material on a substrate, wherein the coating device 1 comprises the vacuum chamber 8, the crucible 6, which is arranged within the vacuum chamber 8, the spray head 7 for preparing the coating material and the injector tube arranged within the vacuum chamber 8, wherein also more than one spray head 7 can be provided for a crucible 6. The injector tube 5 is designed to conduct coating material prepared in the at least one spray head 7 to the crucible 6 and is connected to the crucible 6, wherein the at least one spray head 7 is designed to be movable between the operating position, in which the spray head 7 is arranged to supply the injector tube 5 with the prepared coating material, and a removal position. In this case, the coating device further comprises the removal chamber 12, which is designed to be accessible from outside the vacuum chamber 8 and which is designed to be sealed off from the vacuum chamber 8 and in which the at least one spray head 7 in its removal position is separated in a gas-tight manner from the vacuum chamber 8.

The described invention is of course not limited to the described and illustrated embodiment. It can be seen that numerous modifications, which are obvious to a person skilled in the art according to the intended application, can be made to the embodiment depicted in the drawing without departing from the scope of the invention. For example, a plurality of crucibles 6 can also be arranged in a vacuum chamber 8 in order to allow for a double-sided coating, for example, wherein a plurality of injector tubes 5 can also be attached to a crucible 6, in which a separate spray head 7 is arranged in each case during the operation of the coating device 1. It is also conceivable that the coating device 1 has more than one vacuum chamber 8, wherein one or more crucibles 6 can then be arranged in each individual vacuum chamber 8, each of which being equipped with at least one injector tube 5, in which a spray head 7 is then arranged during operation. The invention includes everything that is contained in the description and/or shown in the drawing, including anything that, deviating from the specific embodiment, is obvious to a person skilled in the art.

List of reference signs

| | |
|---|---|
| 1 | Coating device |
| 2 | Coating material feeds |
| 3 | Coating material feeds (anode) |
| 4 | Gas supply |
| 5 | Injector tube |
| 6 | Crucible |
| 7 | Spray head |
| 8 | Vacuum chamber |
| 9 | Flange |
| 10 | Bellows-like connecting element |
| 11 | Wall portion |
| 12 | Removal chamber |
| 14 | Shutoff valve |
| 15 | Shutoff device |
| 16 | Ventilation valve |
| 17 | Outlet opening |
| 18 | Vacuum feedthrough |
| 19 | Vacuum feedthrough |
| 20 | Chamber wall element |
| 21 | Outer wall |
| 22 | Sealing element |

1. A coating device for depositing a coating material on a substrate, having a vacuum chamber, a crucible, which is arranged within the vacuum chamber, at least one spray head for preparing the coating material and an injector tube arranged within the vacuum chamber, wherein the injector tube is designed to conduct the coating material prepared in the at least one spray head to the crucible and is connected to the crucible, wherein the at least one spray head has an outlet opening for the prepared coating material and is designed to be movable between an operating position, in which the at least one spray head is arranged to supply the injector tube with the prepared coating material, and a removal position, and wherein at least one removal chamber designed to be accessible from outside the vacuum chamber is provided which in the removal position is able to be sealed off from the vacuum chamber in a gas-tight manner and in which at least the outlet opening of the at least one spray head in the removal position of the spray head is separated in a gas-tight manner from the vacuum chamber.

2. The coating device according to claim 1, wherein the at least one spray head has at least one coating material feed and at least one gas supply, wherein, in the operating position of the at least one spray head, the at least one coating material feed and the at least one gas supply are guided through a vacuum feedthrough from outside the vacuum chamber into the vacuum chamber.

3. The coating device according to claim 2, wherein the at least one spray head is attached to a flange which is connected to a wall portion of the vacuum chamber by means of a bellows-like connecting element.

4. The coating device according to claim 3, wherein the bellows-like connecting element forms the at least one removal chamber.

5. The coating device according to claim 3, wherein, in the removal position, the at least one spray head is arranged completely within the bellows-like connecting element.

6. The coating device according to claim 2, wherein a chamber wall element forms the at least one removal chamber and seals it off against the at least one spray head, which is movable from the operating position into the removal position and back, by means of a sealing element.

7. The coating device according to claim 6, wherein the at least one spray head is attached to a flange at its longitudinal end facing away from the outlet opening and wherein the vacuum feedthrough is formed on the flange.

8. The coating device according to claim 3, wherein the vacuum feedthrough is formed on the flange.

9. The coating device according to claim 2, wherein the vacuum feedthrough is formed and arranged within the at least one spray head.

10. The coating device according to claim 1, wherein a shutoff device is movably arranged within the vacuum chamber between a release position and a blocking position, wherein, in the blocking position, the shutoff device separates the at least one spray head arranged in its removal position from the vacuum chamber in a gas-tight manner.

11. The coating device according to claim 1, wherein the at least one removal chamber has a ventilation valve.

12. The coating device according to claim 1, wherein the at least one spray head projects in its operating position at least in portions into the injector tube and the at least one spray head is coaxially movable in the injector tube and guided in a gas-tight manner during a movement from the operating position in the direction of the removal position.

13. The coating device according to claim 1, wherein the injector tube has a shutoff valve which is movable between a release position and a blocking position, wherein the shutoff valve blocks a flow through the injector tube in the blocking position.

14. The coating device according to claim 13, wherein, in the blocking position of the shutoff valve, the at least one spray head is arranged in portions within the injector tube.

15. The coating device according to claim 4, wherein, in the removal position, the at least one spray head is arranged completely within the bellows-like connecting element.
